(19) United States
(12) Patent Application Publication
(10) Pub. No.: US 2013/0050937 A1
(43) Pub. Date: Feb. 28, 2013

(54) FIXING DEVICE FOR USE WITH EXPANSION CARDS IN A COMPUTER

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/279,346

(22) Filed: Oct. 24, 2011

(30) Foreign Application Priority Data
Aug. 25, 2011 (CN) 201110246236.X

(51) Int. Cl. H05K 7/12

(52) U.S. Cl. 361/679.58

(57) ABSTRACT

A fixing device for use with at least one expansion card in a computer chassis includes a support member fixed to the chassis and a fixing member rotatably connected to the support member. The fixing member includes at least one fixing portion to receive the free end of the at least one expansion card and a locking member. The locking member resists against the support member and is restrained by the support member, thereby locking the fixing portion, thereby locking the free end of the at least one expansion card.

### BACKGROUND

1. Technical Field

The present disclosure relates to a device for fixing a number of expansion cards.

2. Description of Related Art

Expansion cards are often used in computers. First ends of expansion cards are generally fixed to a chassis, while second ends of the expansion cards are floating. As a result, when the expansion cards are long and are horizontally fixed to the chassis, the second ends of some of the expansion cards may droop to contact other expansion cards below, and a short circuit may occur.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an assembled, isometric view of an exemplary embodiment of a fixing device in a computer chassis for use with expansion cards.

FIG. 2 is an exploded view of the fixing device and the computer chassis of FIG. 1.

FIG. 3 is an assembled view of the fixing device of FIG. 1.

FIG. 4 is an enlarged view of a fixing member of the fixing device in FIG. 1.

### DETAILED DESCRIPTION

Embodiments of the present disclosure will now be described in detail, with reference to the accompanying drawings.

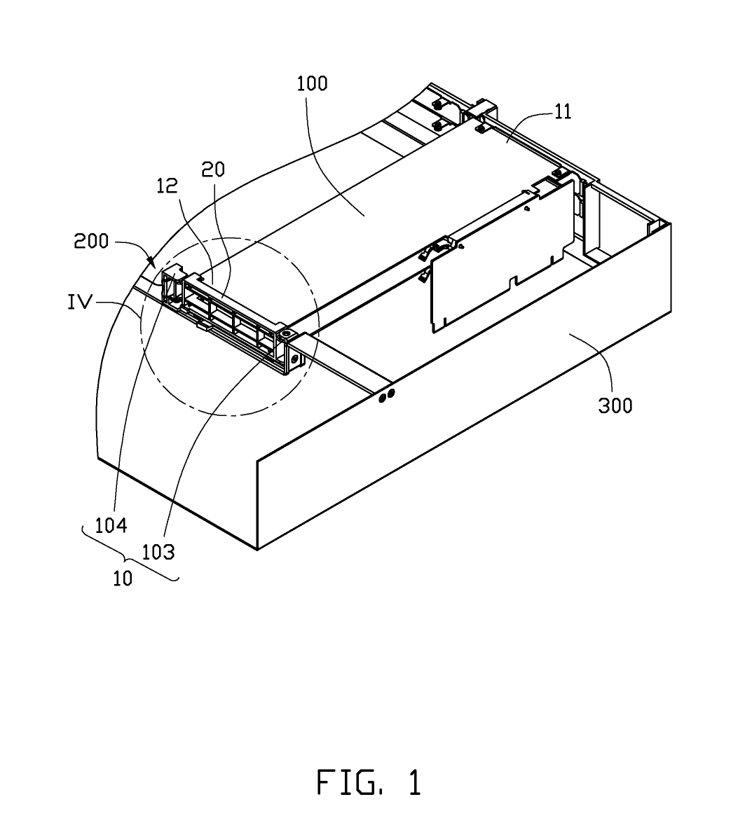

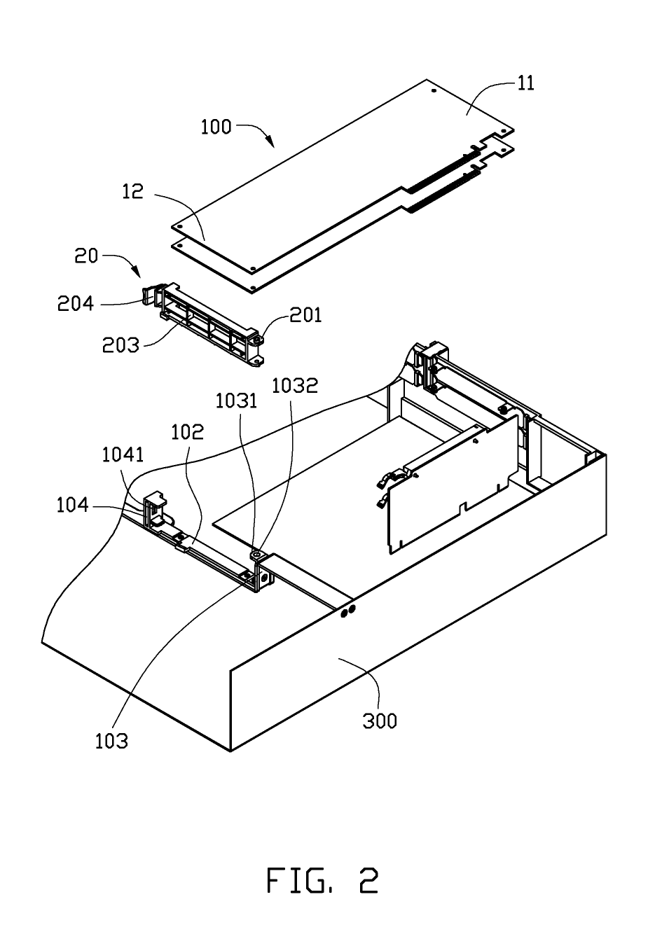

Referring to FIGS. 1-3, an exemplary embodiment of a fixing device 200 for use with at least one plate-shaped element 100 in a computer includes a support member 10 and a fixing member 20. In this embodiment, the plate-shaped element 100 is an expansion card 100 in a computer.

Each of the at least one expansion card 100 includes a first end 11 and a second end 12. The first end 11 is fixed to a sidewall of a computer chassis 300. The fixing device 200 is configured to fix and support the free end 12 of the at least one expansion card 100.

The support member 10 is fixed to chassis 300 and includes a receiving portion 102, a connecting portion 103 connected to one side of the receiving portion 102, and a locking portion 104 connected to another side of the receiving portion 102 and opposite to the connecting portion 103.

The connecting portion 103 includes a projection 1031 positioned above a bottom of the receiving portion 102. The projection 1031 and the bottom of the receiving portion 102 each define a hole 1032 aligned with each other. The locking portion 104 defines a groove 1041 in a sidewall thereof.

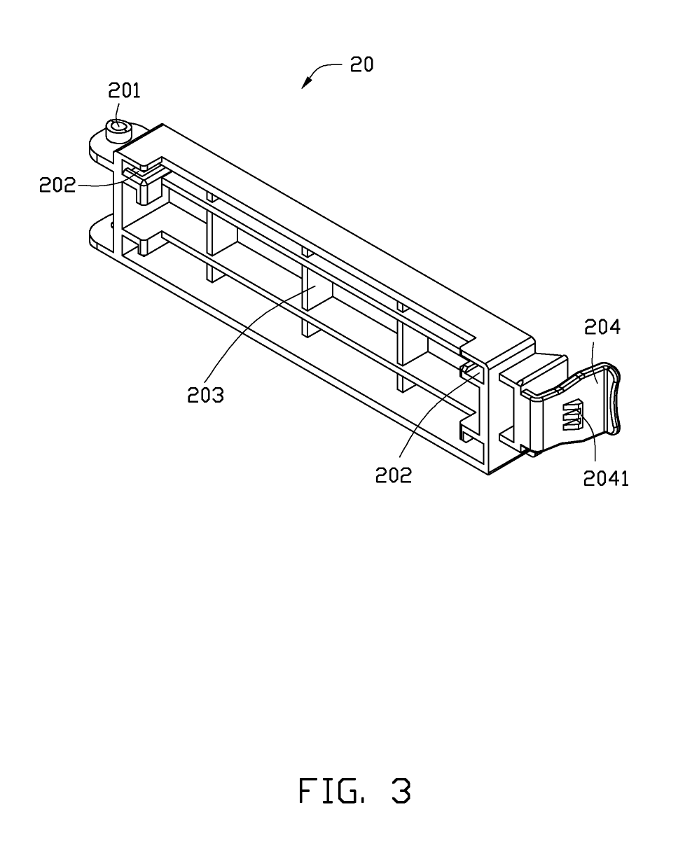

The fixing member 20 is received in the receiving portion 102. Referring to FIG. 3, the fixing member 20 includes two posts 201, a fixing portion 202, a stopper portion 203, and a locking member 204. The two rotatable posts 201 respectively extend from opposite sides of the fixing member 20 and are respectively received in the holes 1032 of the connecting portion 103 and the receiving portion 102, thereby allowing the fixing member 20 to rotate about the posts 201. The fixing portion 202 defines at least one slot to receive the free end 12 of one of the at least one expansion card 100.

The locking member 204 protrudes from an end of the fixing member 20 opposite the posts 201 to engage with the locking portion. A gap is formed between the locking member 204 and end of the fixing member 20 where the locking member 204 protrudes. In this embodiment, the locking member 204 is flexible and can be deflected due to the existence of the gap when pressed. A latch 2041 protrudes from an outer side of the locking member 204.

The stopper portion 203 is arranged between the posts 201 and the locking member 204 and is configured to restrict the movement of the expansion card 100. The stopper portion 203 includes a number of horizontal tabs and a number of vertical tabs running perpendicular to the horizontal tabs.

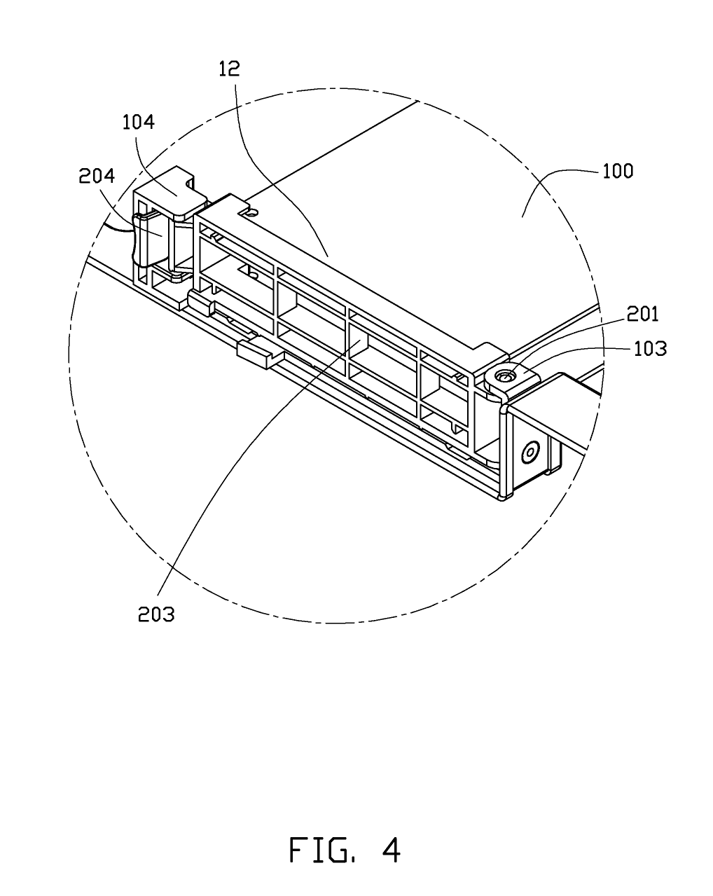

Referring to FIG. 4, during assembly, the first end 11 is first connected to the chassis 300. The fixing member 20 is then rotated toward the at least one expansion card 100 to a position where the fixing portion 202 receives the free end 12 of the at least one card 100. Simultaneously, the locking member 204 resist tightly against the sidewall of the locking portion 104. The latch 2041 is received in the groove 1041, thereby locking the free end 12.

To release the at least one expansion card 100, press the locking member 204 toward the fixing portion 202 to pull the latch 2041 out of the groove 1041, then rotate the fixing member 20 away from the at least one expansion card 100 to release the at least one expansion card 100.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A fixing device for use with at least one expansion card in a computer chassis, each of the at least one expansion card comprising a fixed end fixed to the computer chassis and a free end, the fixing device comprising:
a support member fixed to the chassis; and
a fixing member rotatably connected to the support member and comprising a fixing portion configured to receive the free end of each of the at least one expansion card and a locking member, wherein the locking member resists against the support member and is restrained by the support member, thereby locking the free end of each of the at least one expansion card.

2. The fixing device as described in claim 1, wherein the support member further comprises a receiving portion, a connecting portion connected to one side of the receiving portion, and a locking portion connected to another side of the receiving portion and opposite to the connecting portion; the connecting portion comprises a projection positioned above a bottom of the receiving portion, the projection and the bottom of the receiving portion each define a hole aligned with each other; the fixing member is received in the receiving portion and comprises two posts respectively received in the holes of the projection and the bottom of the receiving portion to allow the fixing member to rotate about the posts.

3. The fixing device as described in claim 2, wherein the locking member protrudes from an end of the fixing member opposite to the posts to engage with the locking portion.

4. The fixing device as described in claim 3, wherein the locking portion further defines a groove on a sidewall thereof, the locking member comprises a latch protruding from an outer side of the locking member, when the locking member resists against the locking portion, the latch insert into the groove to lock the fixing member.

5. The fixing device as described in claim 3, wherein the fixing member further comprises a stopper portion arranged between the posts and the locking member to restrict the movement of the at least one expansion card, wherein the stopper portion comprises a plurality of horizontal tabs and a plurality of vertical tabs running perpendicular to the horizontal tabs.

6. The fixing device as described in claim 3, wherein the locking member is flexible.
